(19) United States
(12) Patent Application Publication
(10) Pub. No.: US 2014/0103401 A1
(43) Pub. Date: Apr. 17, 2014

(54) IMAGE SENSOR

(71) Applicant: Samsung Electronics Co., Ltd., Suwon-Si (KR)

(72) Inventors: Tae-Seok OH, Seoul (KR); Tae-Yon LEE, Seoul (KR); Young-Gu JIN, Osan-si (KR); Min-Ho KIM, Seongnam-si (KR); Tae-Chan KIM, Yongin-si (KR); Sang-Chul SUL, Suwon-si (KR); Kwang-Hyun LEE, Seongnam-si (KR)

(73) Assignee: SAMSUNG ELECTRONICS CO., LTD., Suwon-Si (KR)

(21) Appl. No.: 14/051,040

(22) Filed: Oct. 10, 2013

Related U.S. Application Data
(60) Provisional application No. 61/713,175, filed on Oct. 12, 2012.

(30) Foreign Application Priority Data
Mar. 8, 2013 (KR) 10-2013-0025169

(51) Int. Cl. H01L 27/148

(52) U.S. Cl. CPC H01L 27/14806
USPC 257/231

(57) ABSTRACT

An image sensor is provided. The image sensor includes a well of a second conductivity type formed on an impurity layer of a first conductivity type, source and drain regions of the first conductivity type, formed in the well to be spaced apart from each other, a first photo diode of the first conductivity type formed in the well to overlap the source and drain regions, a second photo diode of the first conductivity type formed so as not to overlap the source and drain regions and formed to be adjacent to the first photo diode, and a gate electrode formed on the first and second photo diodes.

### CROSS-REFERENCE TO RELATED APPLICATION

This application claims the benefit of U.S. Provisional Patent Application No. 61/713,175, filed on Oct. 12, 2012, with the United States patent and Trademark Office, and claims priority to and the benefit of Korean Patent Application No. 10-2013-0025169, filed on Mar. 8, 2013, the entire content of which is incorporated herein by reference.

### BACKGROUND

1. Field of the Invention

The example embodiments relate to an image sensor.

2. Description of the Related Art

An image sensor is one of semiconductor devices that convert optical information into an electric signal. Examples of the image sensor may include a charge coupled device (CCD) image sensor, a complementary metal-oxide semiconductor (CMOS) image sensor, a single electron image sensor being vigorously studied nowadays, and so on.

The image sensor may be configured in the form of a package. The package may protect the image sensor and may be configured such that light is incident into a photo receiving surface or a sensing area of the image sensor.

### SUMMARY

Example embodiments provide an image sensor having improved photoelectric conversion performance and sensing sensitivity while increasing full well capacity of a photo diode.

Example embodiments also provide an image sensor having reduced dark current.

Example embodiments also provide a method for fabricating an image sensor having improved photoelectric conversion performance and sensing sensitivity while increasing full well capacity of a photo diode and having reduced dark current.

These and other objects of the example embodiments will be described in or be apparent from the following description of the following example embodiments.

According to an example embodiment, there is provided an image sensor including a well of a second conductivity type formed on an impurity layer of a first conductivity type, source and drain regions of the first conductivity type, formed in the well to be spaced apart from each other, a first photo diode of the first conductivity type formed in the well to overlap the source and drain regions, a second photo diode of the first conductivity type formed so as not to overlap the source and drain regions and formed to be adjacent to the first photo diode, and a gate electrode formed on the first and second photo diodes.

According to another example embodiment, there is provided an image sensor including a well of a second conductivity type formed on an impurity layer of a first conductivity type, source and drain regions of the first conductivity type, formed in the well to be spaced apart from each other, a photo diode of the first conductivity type formed in the well, a body region of the first conductivity type formed to be in contact with the photo diode, a connection region of the first conductivity type formed to be in contact with the body region while passing through the well, a pad region of the first conductivity type formed at one end of the connection region, and a gate electrode formed on the photo diode.

At least one example embodiment relates to an image sensor having a potential well.

In one embodiment, the image sensor includes a source, a drain and a gate; and a first photodiode and a second photodiode floating in the potential well such that the first photodiode and the second photodiode are not electrically connected to the source and the drain, the first photodiode having a first width and being electrically connected to the gate via the second photodiode having a second width.

In one embodiment, the source, the drain, the gate, the first photodiode and the second photodiode have a p-type conductivity and the well has an n-type conductivity.

In one embodiment, the first photodiode and the second photodiode are configured to vary a threshold voltage of the image sensor based on an amount of light incident thereto.

In one embodiment, the first width of the first photodiode is such that the first photodiode overlaps the source and the drain in a vertical direction and the second width is such that the second photodiode does not overlap the source and the drain in the vertical direction.

In one embodiment, the first photodiode is at a first depth in relation to a top surface of the potential well and the second photodiode is at a second depth in relation to the top surface, first depth being greater than the second depth.

### BRIEF DESCRIPTION OF THE DRAWINGS

The above and other features and advantages of the example embodiments will become more apparent by describing in detail example embodiments thereof with reference to the attached drawings in which:

FIG. 1 is a plan view of an image sensor according to an example embodiment;

FIG. 2 is a cross-sectional view of the image sensor shown in FIG. 1, taken along the line A-A′;

FIG. 3 is a potential diagram illustrated along the line Q-Q′ of FIG. 2;

FIG. 4 is an equivalent circuit diagram of the image sensor shown in FIG. 1;

FIG. 5 is a plan view of an image sensor according to another example embodiment;

FIG. 6 is a cross-sectional view of the image sensor shown in FIG. 5, taken along the line B-B′;

FIG. 7 is a plan view of an image sensor according to still another example embodiment;

FIG. 8 is a cross-sectional view of the image sensor shown in FIG. 7, taken along the line C-C′;

FIG. 9 is a plan view of an image sensor according to still another example embodiment;

FIG. 10 is a cross-sectional view of the image sensor shown in FIG. 9, taken along the line D-D′;

FIG. 11 is a plan view of an image sensor according to still another example embodiment;

FIG. 12 is a cross-sectional view of the image sensor shown in FIG. 11, taken along the line E-E′;

FIGS. 13 to 18 illustrate intermediate process steps for explaining a method for fabricating an image sensor according to an example embodiment; and

FIG. 19 is a schematic block diagram illustrating a processor based system employing an image sensor according to example embodiments.

### DETAILED DESCRIPTION OF THE EMBODIMENTS

Advantages and features of the example embodiments may be understood more readily by reference to the following detailed description of example embodiments and the accompanying drawings. The example embodiments may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the example embodiments.

The example embodiments will be described with reference to perspective views, cross-sectional views, and/or plan views, in which preferred embodiments of the invention are shown. Thus, the profile of an exemplary view may be modified according to manufacturing techniques and/or allowances. That is, the embodiments are not intended to limit the scope of the example embodiments but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

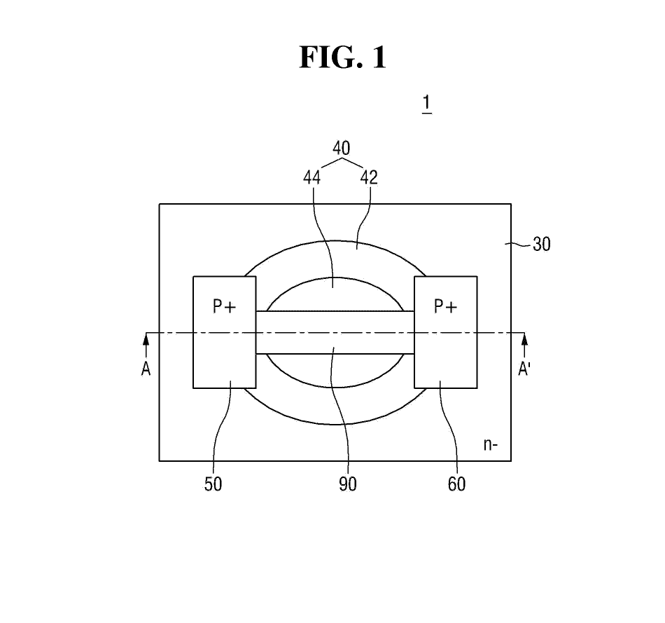

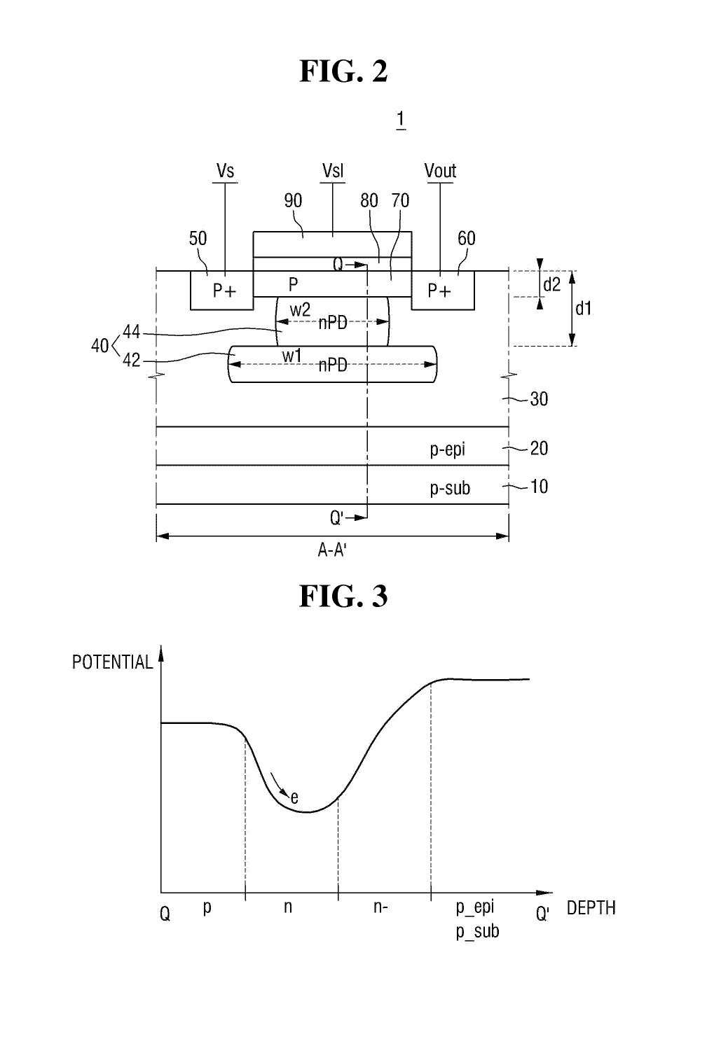

FIG. 1 is a plan view of an image sensor according to an example embodiment of the and FIG. 2 is a cross-sectional view of the image sensor shown in FIG. 1, taken along the line A-A′. FIGS. 1 and 2 illustrate unit pixels of the image sensor.

Referring to FIGS. 1 and 2, a junction transistor 1 may function as an image sensor and include p-type impurity layers 10 and 20, well 30, first and second photo diodes 42 and 44, respectively, a source region 50, a drain region 60, a channel region 70, a gate insulation layer 80, and a gate electrode 90.

As shown, the p-type impurity layers 10 and 20 may include a p-type substrate 10 and a p-type epitaxial layer 20. Although not shown in detail, an isolation layer for defining each unit pixel may be formed in the substrate 10. The p-type epitaxial layer 20 may be formed on the substrate 10 by, for example, epitaxial growth. The epitaxial layer 20 may increase sensing sensitivity of the image sensor.

In some embodiments, the p-type substrate 10 may not be provided when necessary. That is to say, in some embodiments, the p-type impurity layers 10 and 20 may be modified to include only the p-type epitaxial layer 20.

The well 30 may be formed on the p-type impurity layers 10 and may be of, for example, an n-type well. An impurity concentration of the n-type well 30 may be less than that of a photo diode 40 to be described later. For example, the impurity concentration of the n-type well 30 may be, for example, in a range of 1×10¹⁴ to 1×10¹⁷ atoms/cm³. However, the impurity concentration of the n-type well 30 may vary according to the fabrication process and design, but example embodiments are not limited thereto.

The n-type well 30 formed under the photo diode 40 may function as a photoelectric conversion area together with the photo diode 40, which will later be described.

The source region 50 and the drain region 60 may be formed to be spaced apart from each other in the well 30. Conductivity types of the source region 50 and the drain region 60 may be p type. Impurity concentrations of the p-type source region 50 and the drain region 60 may be greater than the impurity concentration of the p-type substrate 10 or the p-type epitaxial layer 20. The impurity concentrations of the p-type source region 50 and the drain region 60 may be, for example, in a range of 1×10¹⁸ to 1×10²² atoms/cm³, but example embodiments are not limited thereto.

The channel region 70 may be formed between the source region 50 and the drain region 60 spaced apart from each other in the well 30 such that the source region 50 and the drain region 60 may be connected to each other through the channel region 70. In the present embodiment, as shown, the channel region 70 may be of a p type. An impurity concentration of the channel region 70 may be, for example, in a range of 2×10¹⁶ to 1×10¹⁹ atoms/cm³, but example embodiments are not limited thereto.

Meanwhile, the channel region 70 may adjust a threshold voltage of the junction transistor 1 constituting the unit pixel of the image sensors shown in FIGS. 1 and 2. In some example embodiments, the channel region 70 may not be provided if necessary.

A photo diode region 40 may be formed under the channel region 70 in the well 30. The photo diode region 40 may include the first photo diode 42 and the second photo diode 44.

In some example embodiments, as shown, the first photo diode 42 may be formed to overlap the source region 50 and the drain region 60. However, as shown, the second photo diode 44 may be formed so as not to overlap the source region 50 and the drain region 60.

In addition, in some example embodiments, as shown, the first photo diode 42 may be formed at a first depth d1 from the top surface of the well 30. However, as shown, the second photo diode 44 may be formed at a second depth d2 from the top surface of the well 30. In some embodiments, the first depth d1 and the second depth d2 may be different from each other. For example, as shown, the first depth d1 may be greater than the second depth d2. That is to say, the second photo diode 44 may be formed on the first photo diode 42 to be in contact with the first photo diode 42.

In addition, in some example embodiments, the first photo diode 42 may be formed to have a first width w1, as shown. The second photo diode 44 may be formed to have a second width w2, as shown. In some embodiments, the first width w1 and the second width w2 may be different from each other. For example, as shown, the first width w1 may be greater than the second width w2. With the aforementioned configurations of the first photo diode 42 and the second photo diode 44, the first photo diode 42 may be formed to overlap the source region 50 and the drain region 60, and the second photo diode 44 may be formed so as not to overlap the source region 50 and the drain region 60.

The photo diode region 40 may be an n-type impurity region formed under the channel region 70. As shown, the photo diode region 40 may be formed to be isolated so as not to be connected to the source region 50 and the drain region 60. Meanwhile, since the photo diode region 40 is formed so as not to be connected to a contact, it may be understood that the photo diode region 40 is formed to float in the well 30.

The photo diode region 40 is a region where electrons generated by incident light are collected, and may function as a photoelectric conversion region. In the present embodiment, the photo diode region 40 may be of an n type, as shown. Here, an impurity concentration of the photo diode region 40 may be, for example, in a range of 1×10¹⁶ to 1×10¹⁹ atoms/cm³, which may be greater than that of the n-type well 30, but example embodiments are not limited thereto.

A gate insulation layer 80 and a gate electrode 90 may be formed on the photo diode 40 and the channel region 70 such that the gate electrode 90 may be formed on the well 30.

In the present embodiment, the well 30, the photo diode region 40, the source region 50, the drain region 60, the channel region 70 and the gate electrode 90 may constitute the junction transistor 1. The junction transistor 1 may operate according to the quantity of electrons collected in the photo diode 40. The junction transistor 1 constitutes each pixel of an image sensor, and may function as a photoelectric conversion element and a sensing element. That is to say, the junction transistor 1 may perform functions of both of the photoelectric conversion element and the sensing element.

Hereinafter, the function of the photoelectric conversion element of the junction transistor 1 will be described with reference to FIGS. 1 to 3.

FIG. 3 is a potential diagram illustrated along the line Q-Q′ of FIG. 2.

Referring to FIG. 3, the channel region 70, the photo diode 40, the well 30, the epitaxial layer 20 and the substrate 10, shown in FIG. 2, may constitute a potential well. Therefore, the electrons generated by the light incident into the image sensor or the well 30 may be trapped in the potential well constituted by the photo diode 40. Accordingly, the photo diode 40 and the well 30 shown in FIGS. 1 and 2 may function as photoelectric conversion elements.

Next, the function of the sensing element of the junction transistor 1 will be described with reference to FIGS. 1, 2 and 4.

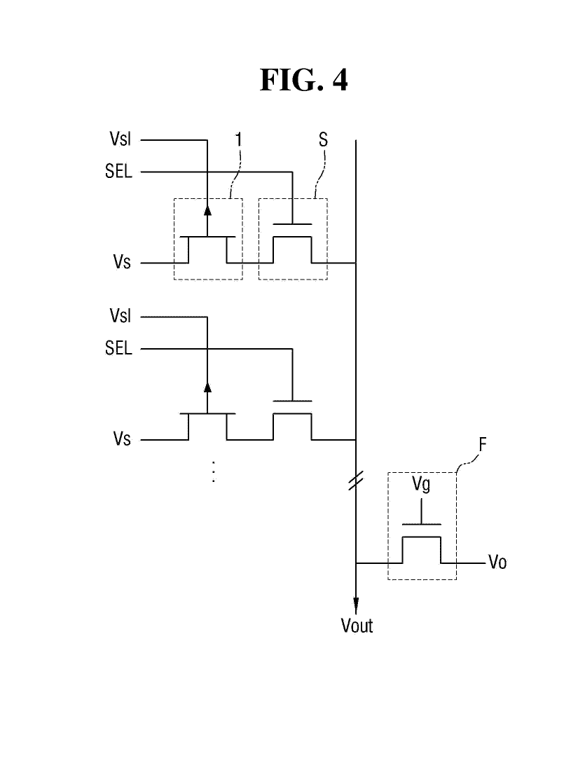

FIG. 4 is an equivalent circuit diagram of the image sensor shown in FIG. 1.

Referring to FIG. 4, the image sensor has the junction transistor 1 and a select transistor S coupled to each other, and the select transistor S is connected to a source follow transistor F. That is to say, in the image sensor according to the present embodiment, the junction transistor 1, the select transistor S and the source follow transistor F may constitute a unit pixel.

The junction transistor 1 senses the electrons generated by light. A source voltage Vs is applied to a source of the junction transistor 1, and the threshold voltage of the junction transistor 1 is determined according to the amount of incident light.

The select transistor S is turned on by a bias supplied by a row select line SEL. The source follow transistor F is coupled to the junction transistor 1 by the select transistor S. Therefore, if the select transistor S is turned on, the junction transistor 1 and the source follow transistor F are electrically connected to each other.

### Reset Operation

A reset operation is an operation for eliminating all of the electrons collected in the photo diode 40 by photoelectric conversion. In order to eliminate all of the electrons collected in the photo diode 40, a voltage greater than or equal to, for example, a first voltage, may be applied to the substrate 10. Then, the electrons collected in the photo diode 40 may escape to the substrate 10. In addition, a second voltage different from the first voltage may be applied to the source region 50 and the drain region 60. If the second is applied to the source region 50 and the drain region, the electrons may escape to the source region 50 and the drain region 60 via the channel region 70.

### Sensing Operation

A sensing operation is an operation for sensing an amount of the light incident to the unit pixel. If the source follow transistor F and the junction transistor 1 are operated in a saturation region, they are controlled only by a voltage between a gate and a source. Meanwhile, as described above, the threshold voltage of the junction transistor 1 varies according to the quantity of the electrons collected in the photo diode 40.

An output voltage Vout proportional to the voltage Vs1 applied to the gate of the junction transistor 1 is output from the source of the source follow transistor F connected to the drain region of the junction transistor 1. Therefore, a change in the output voltage Vout output according to the voltage Vs1 applied to the gate of the junction transistor 1 is sensed, thereby sensing the quantity of the electrons collected in the photo diode 40, that is, the amount of the light incident into unit pixel.

The photo diode 40 of the junction transistor 1 performing functions of photoelectric conversion and sensing includes a first photo diode 42 and a second photo diode 44. With the configurations of the photo diode 40, full well capacity of the photo diode 40, meaning electron storage capacity, can be increased.

As the image sensor becomes gradually small-sized, the size of the photo diode included therein is gradually reduced. Therefore, unlike in the present embodiment, if the photo diode 40 includes only the first photo diode 42 or the second photo diode 44, the quantity of electrons to be stored in the photo diode may be reduced according if the photo diode is reduced in size to a small-sized photo diode. However, in the present embodiment, the photo diode 40 includes the first photo diode 42 and the second photo diode 44 having different configurations, the electron storage capacity of the photo diode 40 can be improved. In addition, since the photoelectric conversion and sensing performance of the junction transistor 1 are simultaneously improved, the performance of the image sensor can be ultimately improved.

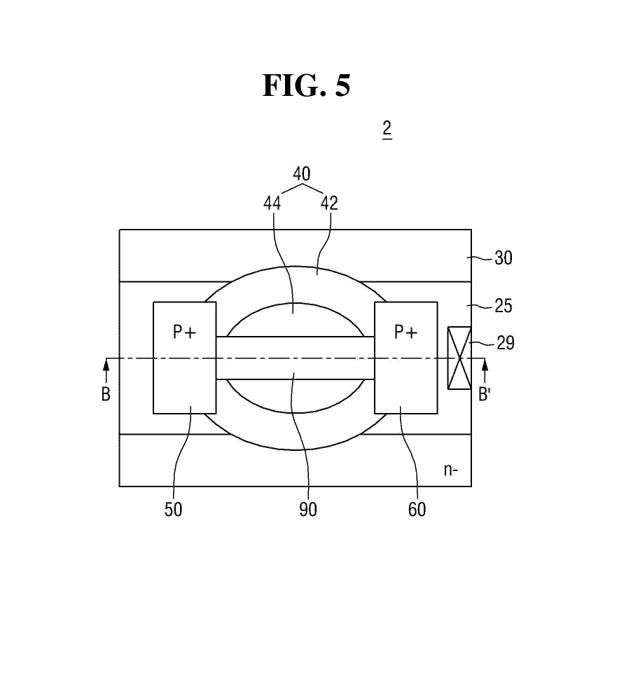

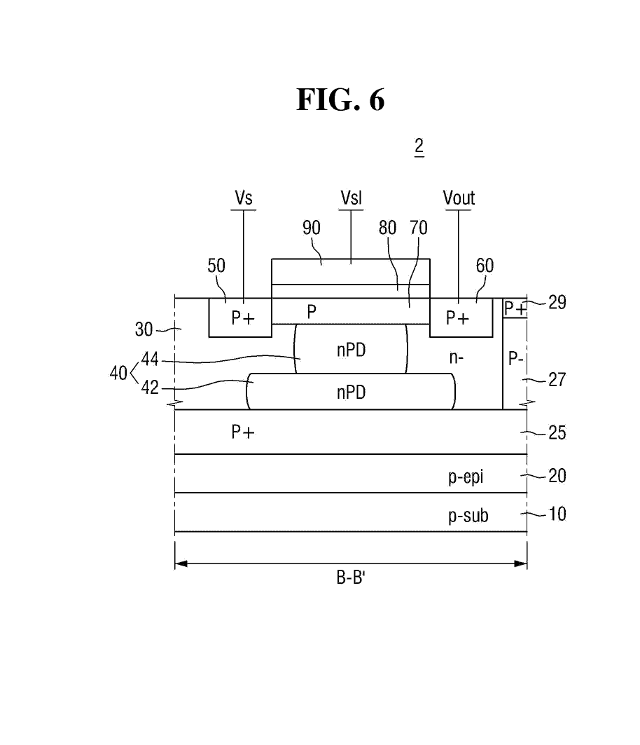

FIG. 5 is a plan view of an image sensor according to another example embodiment and FIG. 6 is a cross-sectional view of the image sensor shown in FIG. 5, taken along the line B-B′.

FIGS. 5 and 6 also illustrate unit pixels of an image sensor. Details, which are the same as those of the previous embodiment, will be omitted and the following description will focus on differences between the present example embodiment and example embodiment of FIGS. 1 and 2.

Referring to FIGS. 5 and 6, a junction transistor 2 of the image sensor according to the present example embodiment may further include a body region 25, a connection region 27, and a pad region 29.

The body region 25 may be formed to be in contact with the first photo diode 42. In detail, the body region 25 may be formed on the epitaxial layer 20 to be in contact with a bottom surface of the first photo diode 42. The body region 25 may be, for example, p-type. An impurity of the body region 25 may be greater than that of the substrate 10 and the epitaxial layer 20.

The connection region 27 may be formed to be in contact with the body region 25. For example, the connection region 27 may be formed to be in contact with the body region 25 while passing through the well 30. The connection region 27 may be of, for example, p type. In addition, an impurity concentration of the connection region 27 may be smaller than that of the body region 25.

The pad region 29 may be formed at one end of the connection region 27. For example, the pad region 29 may be formed at a top end of the connection region 27. The pad region 29 may be electrically connected to a contact wiring formed on the pad region 29 to receive a voltage from the outside. The pad region 29 may be of, for example, a p type. In addition, an impurity concentration of the pad region 29 may be smaller than that of the connection region 27.

During the reset operation of the image sensor, a positive voltage may be applied to the pad region 29 of the junction transistor 2 according to the present embodiment. If the positive voltage is applied to the pad region 29, the electrons generated due to defects included in the substrate 10 or the epitaxial layer 20 may escape to the outside through the body region 25, the connection region 27, and the pad region 29. In addition, the remaining electrons to be eliminated from the photo diode 40 may also escape to the outside through the body region 25, the connection region 27, and the pad region 29.

In general, the electrons generated due to the defects included in the substrate 10 or the epitaxial layer 20, irrespective of the photoelectric conversion operation, may generate dark current, thereby adversely affecting the reliability of the image sensor. With the configuration of the image sensor according to the present embodiment, the dark current can be reduced and the reset function of the photo diode 40 can be improved, thereby improving the reliability of the image sensor.

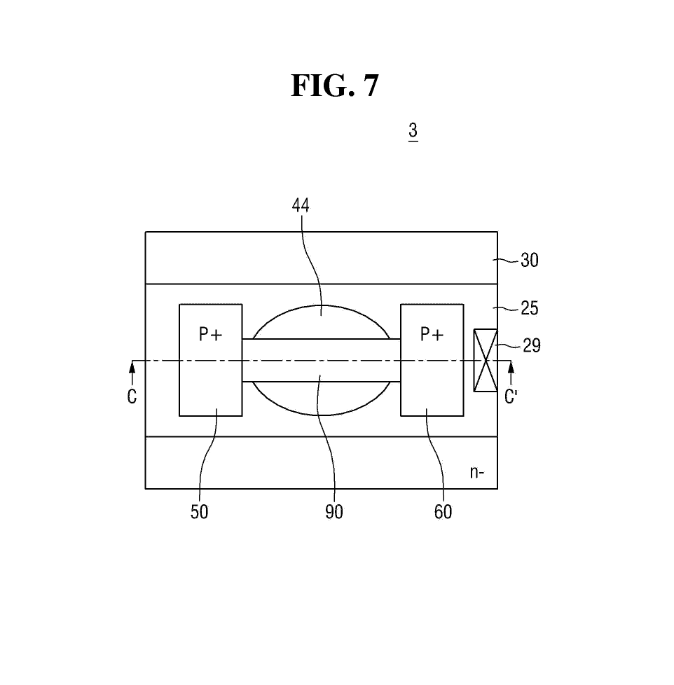

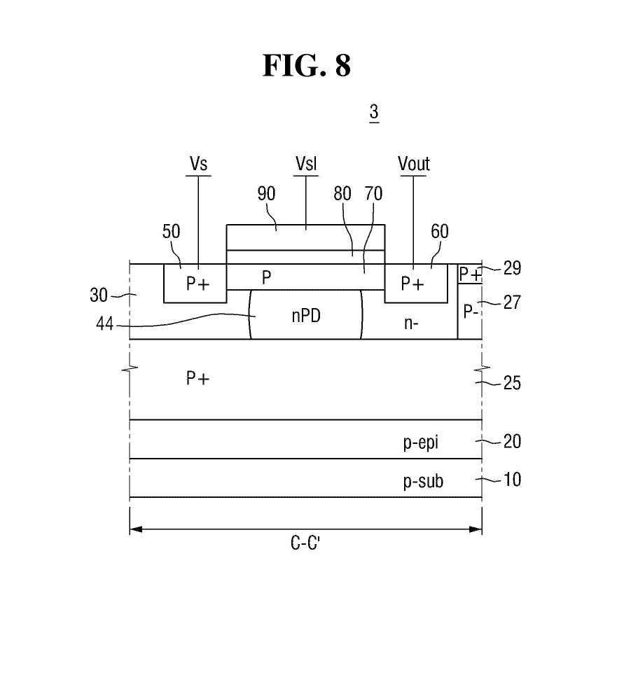

FIG. 7 is a plan view of an image sensor according to still another example embodiment and FIG. 8 is a cross-sectional view of the image sensor shown in FIG. 7, taken along the line C-C′.

FIGS. 7 and 8 also illustrate unit pixels of an image sensor. Details, which are the same as those of the previous embodiment, will be omitted and the following description will focus on differences between the present example embodiment and the example embodiments of FIGS. 5 and 6.

Referring to FIGS. 7 and 8, a junction transistor 3 of the image sensor according to the present example embodiment may be different from the junction transistor (2 of FIG. 6) according to the previous embodiment in view of a configuration of a photo diode 44. In detail, unlike in the junction transistor (2 of FIG. 6) according to the previous embodiment, in which the photo diode 40 includes the first photo diode 42 and the second photo diode 44, in the junction transistor 3 according to the present embodiment, only the second photo diode 44 performs a function of photoelectric conversion.

With the configuration of the image sensor according to the present example embodiment, the electrons generated due to defects included in a substrate 10 or an epitaxial layer 20, irrespective of the photoelectric conversion operation, may be eliminated. In addition, dark current can be reduced and the reset function of the photo diode 44 can be improved, thereby improving the reliability of the image sensor according to the present embodiment.

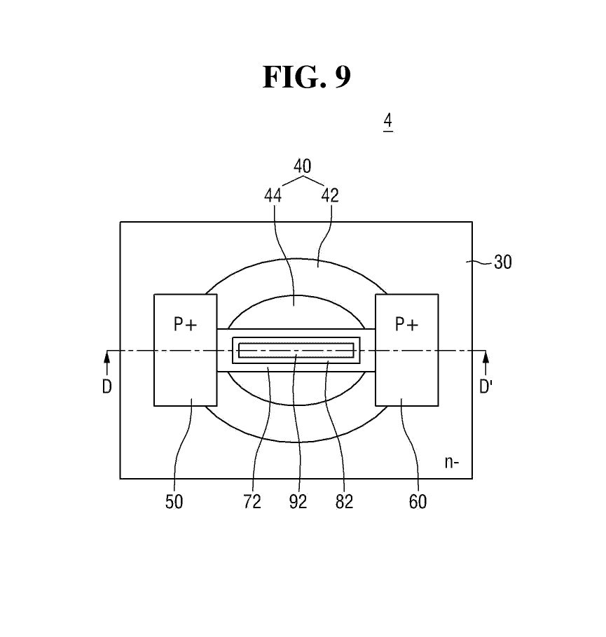

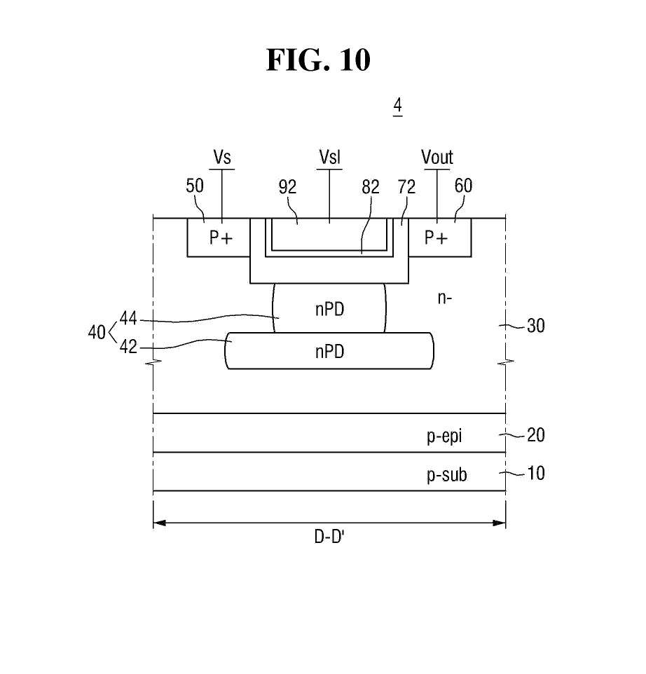

FIG. 9 is a plan view of an image sensor according to still another example embodiment and FIG. 10 is a cross-sectional view of the image sensor shown in FIG. 9, taken along the line D-D′.

FIGS. 9 and 10 also illustrate unit pixels of an image sensor. Details, which are the same as those of the previous embodiment, will be omitted and the following description will focus on differences between the present example embodiment and the example embodiment of FIGS. 7 and 8.

Referring to FIGS. 9 and 10, in a junction transistor 4 of the image sensor according to the present example embodiment, a gate electrode 92 may have a recess gate structure. In detail, the gate electrode 92 may be formed in a well 30, and a gate insulation layer 82 and a channel region 72 may also be formed in the well 30 in such a manner that they surround the gate electrode 92.

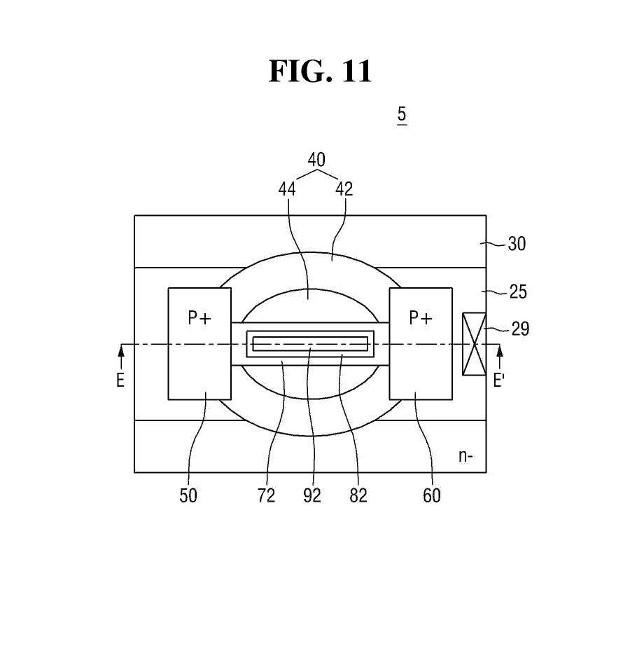

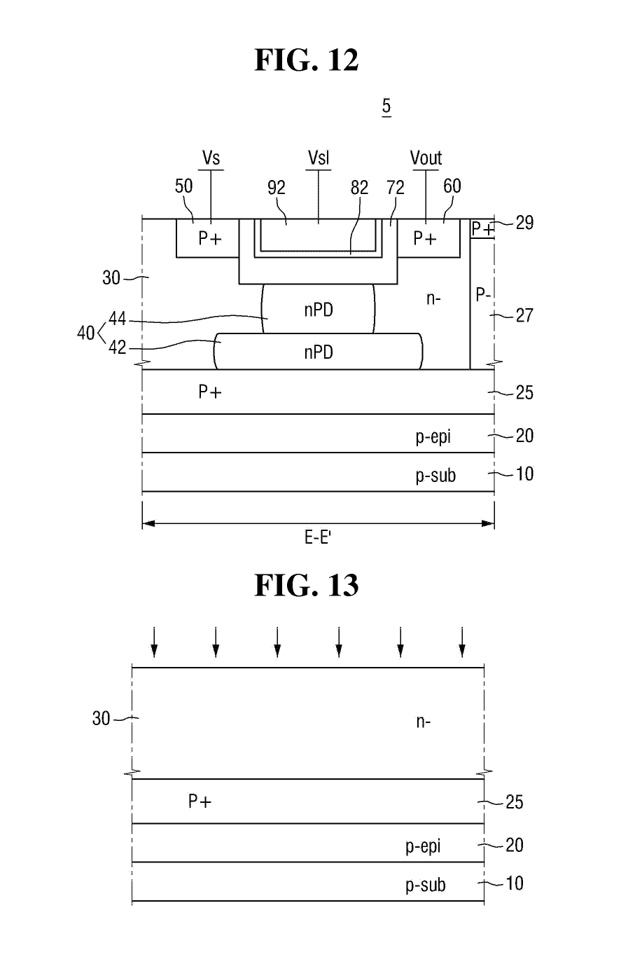

FIG. 11 is a plan view of an image sensor according to still another example embodiment and FIG. 12 is a cross-sectional view of the image sensor shown in FIG. 11, taken along the line E-E′.

FIGS. 11 and 12 also illustrate unit pixels of an image sensor. Details, which are the same as those of the previous embodiment, will be omitted and the following description will focus on differences between the present example embodiment and the example embodiment of FIGS. 9 and 10.

Referring to FIGS. 11 and 12, compared to the junction transistor 4 of the image sensor according to the example embodiment of FIGS. 9 and 10, a junction transistor 5 of the image sensor according to the present embodiment may further include a body region 25, a connection region 27, and a pad region 29. The body region 25, the connection region 27, and the pad region 29 are the same as those fully described in the example embodiments of FIGS. 5-8, and repeated explanations thereof will be omitted.

Next, a method for fabricating an image sensor according to an example embodiment will be described with reference to FIGS. 13 to 18.

FIGS. 13 to 18 illustrate intermediate process steps for explaining a method for fabricating an image sensor according to an example embodiment.

First, referring to FIG. 13, a p-type epitaxial layer 20 may be formed on a p-type substrate 10 by, for example, epitaxial growth. In some example embodiments, the p-type substrate 10 may not be provided if necessary.

Second, an n-type well 30 may be formed on the epitaxial layer 20. The forming of the well 30 may also be performed by, for example, epitaxial growth.

Third, a p-type body region 25 may be formed in the well 30 by, for example, ion implantation. Here, the body region 25 may be formed at the deepest region of the well 30, as shown in FIG. 13.

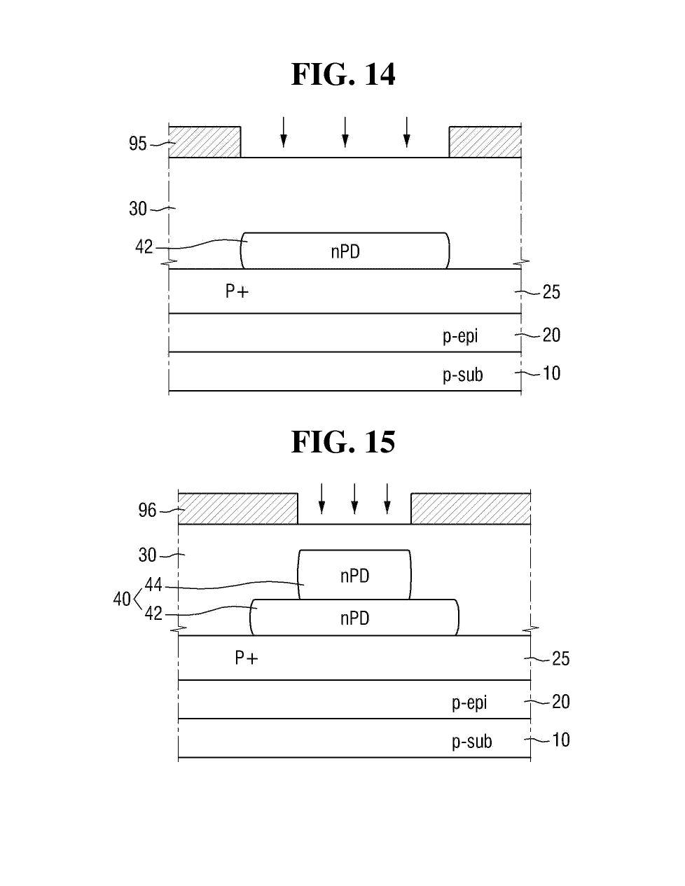

Fourth, referring to FIG. 14, a first mask 95 is formed on the well 30 to be spaced a first width (w1 of FIG. 2) apart from the well 30.

Fifth, an n-type first photo diode 42 is formed by, for example, ion implantation. Here, the first photo diode 42 may be positioned at a first depth (d1 of FIG. 2) of the well 30 and may be formed to be in contact with the body region 25.

Sixth, referring to FIG. 15, a second mask 96 is formed on the well 30 to be spaced a second width (w2 of FIG. 2) smaller than the first width (w1 of FIG. 2) apart from the well 30.

Seventh, an n-type second photo diode 44 is formed by, for example, ion implantation. Here, the second photo diode 44 may be positioned at a second depth (d2 of FIG. 2) of the well 30 and may be formed to be in contact with the first photo diode 42. In addition, a width of the second photo diode 44 formed by the fabricating process may be smaller than that of the first photo diode 42.

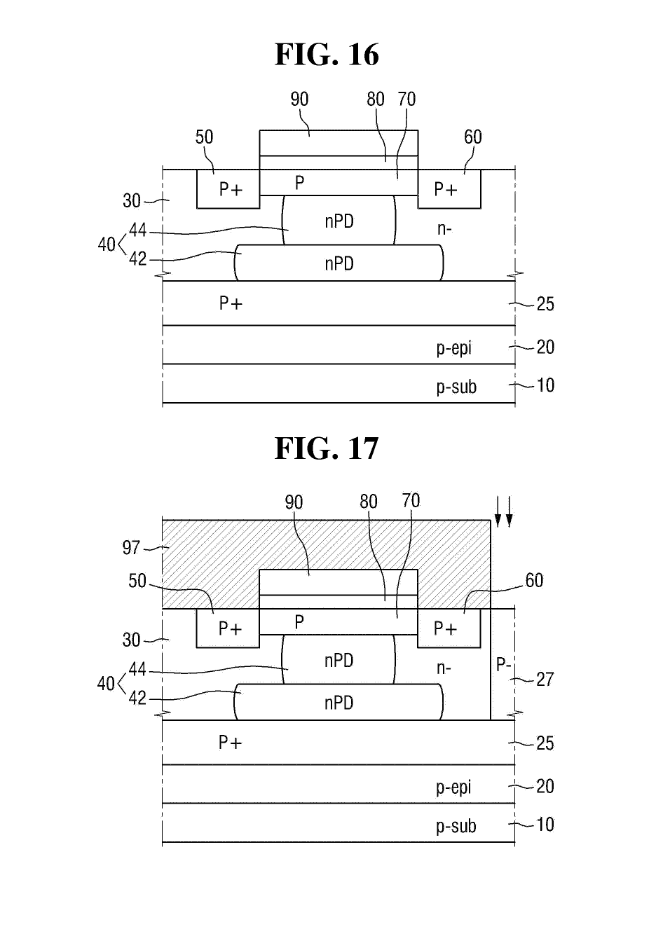

Eighth, referring to FIG. 16, a p-type source region 50 and a p-type drain region 60 spaced apart from each other, and a p-type channel region 70 interposed between the source region 50 and the drain region 60 are formed in the well 30. In some example embodiments, the forming of the channel region 70 may be skipped. As shown in FIG. 16, the source region 50 and the drain region 60 may be formed to overlap the first photo diode 42 while not overlapping the second photo diode 44.

Ninth, a gate insulation layer 80 and a gate electrode 90 are sequentially formed on the well 30. In the present example embodiment, the gate electrode 90 may be formed on the second photo diode 44, as shown in FIG. 16.

Tenth, referring to FIG. 17, a third mask 97 covering the source region 50, gate electrode 90, and the drain region 60 is formed on the well 30.

Eleventh, ion implantation, for example, may be performed on a top surface of the exposed well 30, thereby forming a p-type connection region 27 passing through the well 30. Here, the connection region 27 is formed to be in contact with the body region 25.

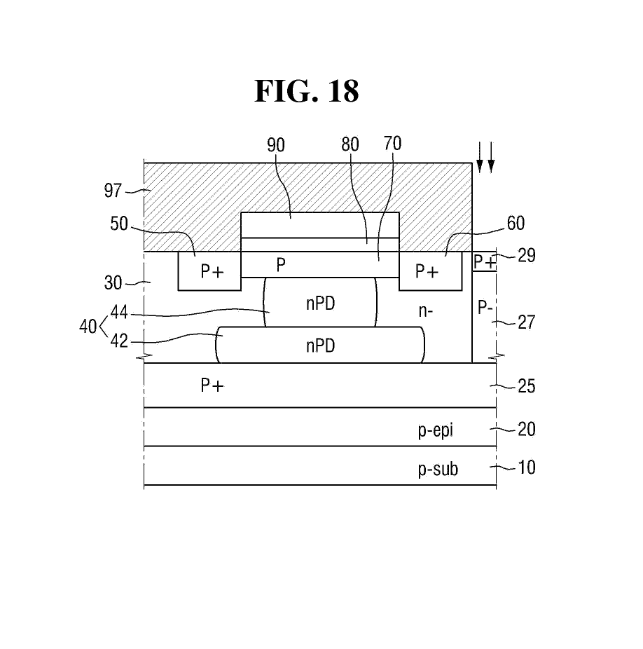

Twelfth, referring to FIG. 18, a p-type pad region 29 is formed at a top end of the connection region 27 by, for example, ion implantation. The pad region 29 may function as a contact pad to which an external voltage is applied.

In the foregoing description, the method for fabricating the image sensor according to an example embodiment, as shown in FIGS. 5 and 6, has been described by way of example. Since undefined image sensors according to other example embodiments may also be fabricated by a method similar to the aforementioned method, repeated explanations thereof will be omitted.

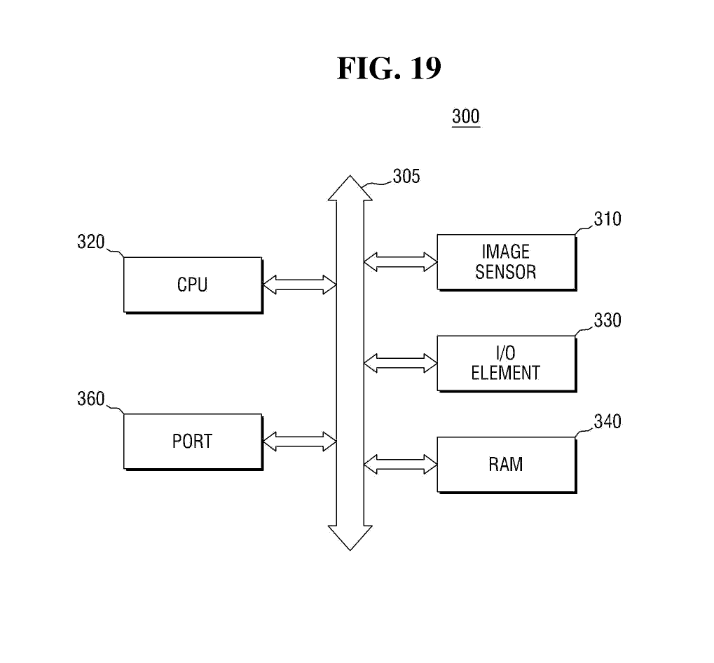

Hereinafter, a processor based system employing an image sensor according to example embodiments will be described with reference to FIG. 19.

FIG. 19 is a schematic block diagram illustrating a processor based system employing an image sensor according to example embodiments.

Referring to FIG. 19, a processor based system 300 may be, for example, a system for processing an image output from the image sensor 310. The processor based system 300 may be exemplified by a computer system, a camera system, a scanner, a mechanized clock system, a navigation system, a videophone, a monitoring system, an auto-focusing system, a tracking system, a motion surveillance system, an image stabilizing system, a tablet PC, a notebook computer, a cellular phone, and so on, but not limited thereto.

The processor based system 300, such as a computer system, includes a central information unit (CPU) 320, such as a microprocessor, capable of communicating with an input/output (I/O) device 330 through a bus 305. The image sensor 310 may communicate with the system through the bus 305 or other communication links. Here, the image sensors 1 to 5 according to the above-described example embodiments may be employed as the image sensor 310.

Meanwhile, the processor based system 300 may further include a random access memory (RAM) 340 and/or a port 360 capable of communicating with the CPU 320 through the bus 305. The port 360 may be coupled to a video card, a sound card, a memory card, a universal serial bus (USB) or a port capable of communicating data with respect to another system. The image sensor 310 may be integrated with the CPU 320, a digital signal processor (DSP) or a microprocessor. In addition, the image sensor 310 may be integrated with a memory. In some cases, the image sensor 310 may be integrated into a chip separately from the processor.

If the processor based system 300 is a wireless communicable apparatus, it may be used in a communication system such as code division multiple access (CDMA), global system for mobile communication (GSM), North American digital cellular (NADC), enhanced-time division Multiple access (E-TDMA), a wideband code division multiple access (WCDAM), and CDMA2000.

While example embodiments have been particularly shown and described with reference to example embodiments thereof, it will be understood by those of ordinary skill in the art that various changes in form and details may be made therein without departing from the spirit and scope of the present invention as defined by the following claims. It is therefore desired that the present example embodiments be considered in all respects as illustrative and not restrictive, reference being made to the appended claims rather than the foregoing description to indicate the scope of the invention.

1. An image sensor comprising:
an impurity layer having a first conductivity type having a well of a second conductivity type formed thereon;
a source and drain region having the first conductivity type formed in the well, the source region spaced apart from the drain region;
a first photo diode having the first conductivity type formed in the well such that the first photo diode overlaps the source and drain regions;
a second photo diode having the first conductivity type formed so as not to overlap the source and drain regions, the second photo diode formed adjacent to the first photo diode; and
a gate electrode formed on the second photo diode.

2. The image sensor of claim 1, wherein a first depth of the first photo diode measured from a top surface of the well is different from a second depth of the second photo diode measured from the top surface.

3. The image sensor of claim 2, wherein the first depth is greater than the second depth.

4. The image sensor of claim 1, wherein a first width of the first photo diode is different from a second width of the second photo diode.

5. The image sensor of claim 4, wherein the first width is greater than the second width.

6. The image sensor of claim 1, wherein the gate electrode is formed on the well.

7. The image sensor of claim 2, wherein the gate electrode is formed in the well.

8. The image sensor of claim 1, further comprising:
a channel region having the second conductivity type formed between the source region and the drain region, wherein the impurity layer includes an epitaxial layer having the first conductivity type.

9. The image sensor of claim 8, wherein the impurity layer further comprises:
a semiconductor substrate having the first conductivity type positioned under the epitaxial layer.

10. The image sensor of claim 1, wherein the first conductivity type is a p type, and the second conductivity type is an n type.

11. The image sensor of claim 1, further comprising:
a body region having the first conductivity type formed such that the body region contacts the first photo diode;
a connection region having the first conductivity type formed such that the connection region passes through the well and contacts the body region; and
a pad region having the first conductivity type formed at one end of the connection region.

12.-15. (canceled)

16. An image sensor having a potential well, the image sensor comprising:
a source, a drain and a gate; and
a first photodiode and a second photodiode floating in the potential well such that the first photodiode and the second photodiode are not electrically connected to the source and the drain, the first photodiode having a first width and being electrically connected to the gate via the second photodiode having a second width greater than the first width.

17. The image sensor of claim 16, wherein the source, the drain, the gate, the first photodiode and the second photodiode have a p-type conductivity and the well has an n-type conductivity.

18. The image sensor of claim 16, wherein the first photodiode and the second photodiode are configured to vary a threshold voltage of the image sensor based on an amount of light incident thereto.

19. The image sensor of claim 16, wherein the first width of the first photodiode is such that the first photodiode overlaps the source and the drain in a vertical direction and the second width is such that the second photodiode does not overlap the source and the drain in the vertical direction.

20. The image sensor of claim 16, wherein the first photodiode is at a first depth in relation to a top surface of the potential well and the second photodiode is at a second depth in relation to the top surface, first depth being greater than the second depth.
